(19) United States
(12) Patent Application Publication
(10) Pub. No.: US 2023/0197123 A1
(43) Pub. Date: Jun. 22, 2023

(54) METHOD AND APPARATUS FOR PERFORMING A SIMULATED WRITE OPERATION

(71) Applicant: Advanced Micro Devices, Inc., Santa Clara, CA (US)

(72) Inventors: Anwar Kashem, Boxborough, MA (US); Pouya Najafi Ashtiani, Munich (DE); Craig Daniel Eaton, Austin, TX (US); Kedarnath Balakrishnan, Bangalore (IN)

(73) Assignee: Advanced Micro Devices, Inc., Santa Clara, CA (US)

(21) Appl. No.: 17/556,958

(22) Filed: Dec. 20, 2021

(51) Int. Cl. G11C 7/10; G11C 7/22; G11C 5/14

(52) U.S. Cl. CPC G11C 7/1069; G11C 7/1096; G11C 7/222; G11C 5/14

(57) ABSTRACT

A method and apparatus for performing a simulated write in a computer system includes, responsive to a scheduled memory operation determined by a memory controller, sending a simulated write operation to a physical layer circuitry (PHY) to increase circuit power without enabling the output of the PHY until the memory operation begins. Responsive to the memory operation being complete, sending a simulated write operation to the PHY to decrease circuit power.

### BACKGROUND

During a period where a data write or read to memory occurs from an idle period, there is a power increase that must occur to perform the read or write. Depending on how many memory channels require a read or write to occur somewhat simultaneously, the amount of power ramp up to proceed from the idle state to the read or write state may be substantial.

### BRIEF DESCRIPTION OF THE DRAWINGS

A more detailed understanding can be had from the following description, given by way of example in conjunction with the accompanying drawings wherein:

FIG. 1 is a block diagram of an example device in which one or more features of the disclosure can be implemented;

FIG. 2 is a block diagram of a portion of the example system of FIG. 1;

FIG. 3 is an example timing diagram depicting a read and write operation to a memory area of the example system of FIG. 1;

FIG. 4 is an example timing diagram depicting a read and write operation to a memory area including a series of simulated writes;

FIG. 5 is an example block diagram of a physical (PHY) layer during a simulated write operation; and

FIG. 6 is a flow diagram of an example method of performing a simulated write operation in accordance with an embodiment.

### DETAILED DESCRIPTION

Although the method and apparatus will be expanded upon in further detail below, briefly a method for performing a simulated write (also referred to herein as a phantom write) is described herein. During a read or write operation from an idle operation, an increase in power is incurred to perform the operation.

Depending on the number of reads/writes that may occur in a substantially simultaneous time across multiple memory channels, the amount of power to raise the circuitry required to perform the read or write to a level to perform the operation may have significant variation over a very short period. That is, if many read or write operations are to be performed at once, circuitry in the physical layer (PHY) that accesses the memory banks in a memory may need to draw more power than is immediately available from the power supply system, resulting in potential errors occurring.

In order to alleviate this occurrence, described herein is a technique for introducing a phantom write, which is a simulated write operation that does not involve all of the attributes of a conventional write operation. The phantom write operation increases power from the idle state prior to or following a read write event incrementally in the PHY to avoid a large individual increase or decrease in power.

Further, although described in further detail below, an SOC is a device where many components of an entire system are resident on a chip. For example, an SOC may include a processor, memory, storage, input and output drivers, and other components on a single chip.

A method for performing a simulated write in a computer system includes, responsive to a scheduled memory operation determined by a memory controller, sending a simulated write operation to a physical layer circuitry (PHY) to increase circuit power without enabling the output of the PHY until the memory operation begins. Responsive to the memory operation being complete, sending a simulated write operation to the PHY to decrease circuit power.

A computer system for performing a simulated write includes a physical layer circuitry (PHY), and a memory controller operatively coupled with and in communication with the PHY. The memory controller, responsive to a scheduled memory operation, sends a simulated write operation to the PHY to increase circuit power without enabling the output of the PHY until the memory operation begins. The memory controller, responsive to the memory operation being complete, sends a simulated write operation to the PHY to decrease circuit power.

A memory controller operatively coupled with and in communication with a physical layer circuitry (PHY), includes a processor. The processor, responsive to a scheduled memory operation, sends a simulated write operation to the PHY to increase circuit power without enabling the output of the PHY until the memory operation begins. The processor, responsive to the memory operation being complete, sends a simulated write operation to the PHY to decrease circuit power.

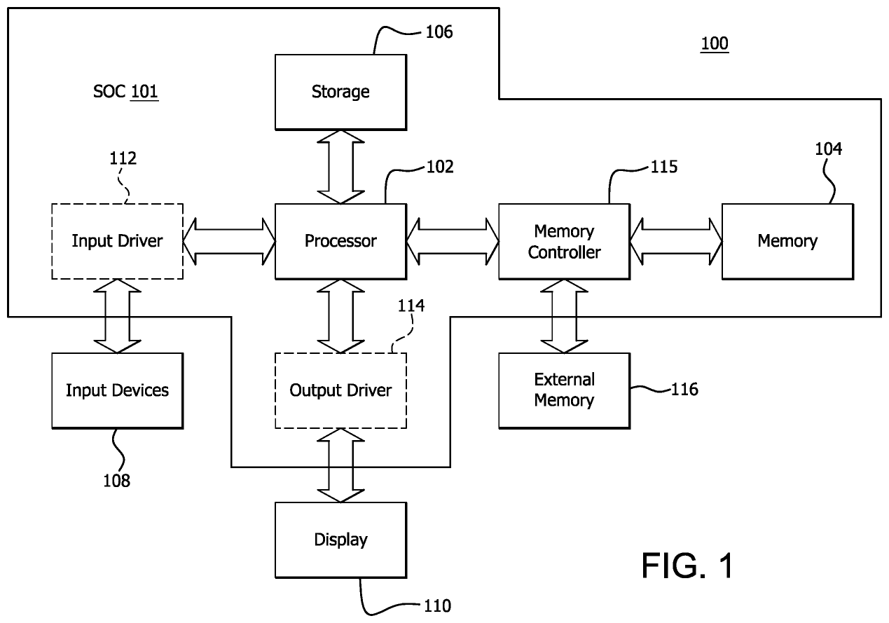

FIG. 1 is a block diagram of an example device 100 in which one or more features of the disclosure can be implemented. The device 100 can include, for example, a computer, a server, a gaming device, a handheld device, a set-top box, a television, a mobile phone, or a tablet computer. The device 100 includes a processor 102, a memory 104, a storage 106, one or more input devices 108, and one or more output devices 110. For purposes of example, the output device 110 is shown as being a display 110, however, it is understood that other output devices could be included.

The device 100 can also optionally include an input driver 112 and an output driver 114. Additionally, the device 100 includes a memory controller 115 that communicates with the processor 102 and the memory 104, and also can communicate with an external memory 116. In some embodiments, memory controller 115 will be included within processor 102 It is understood that the device 100 can include additional components not shown in FIG. 1.

As discussed above, the processor 102, memory 104, storage 106, input driver 112, output driver 114 and memory controller 115 may be included on an SOC 101. Additionally, the memory controller 115 may include a processor, or processing circuitry, for performing operations.

In various alternatives, the processor 102 includes a central processing unit (CPU), a graphics processing unit (GPU), a CPU and GPU located on the same die, or one or more dies, wherein each processor die can be a CPU or a GPU. In various alternatives, the memory 104 is located on the same die as the processor 102, or is located separately from the processor 102. The memory 104 includes a volatile or non-volatile memory, for example, random access memory (RAM), dynamic RAM, or a cache.

The storage 106 includes a fixed or removable storage, for example, a hard disk drive, a solid state drive, an optical disk, or a flash drive. The input devices 108 include, without limitation, a keyboard, a keypad, a touch screen, a touch pad, a detector, a microphone, an accelerometer, a gyroscope, a biometric scanner, or a network connection (e.g., a wireless local area network card for transmission and/or reception of wireless IEEE 802 signals). The output devices 110 include, without limitation, a display, a speaker, a printer, a haptic feedback device, one or more lights, an antenna, or a network connection (e.g., a wireless local area network card for transmission and/or reception of wireless IEEE 802 signals).

The input driver 112 communicates with the processor 102 and the input devices 108, and permits the processor 102 to receive input from the input devices 108. The output driver 114 communicates with the processor 102 and the output devices 110, and permits the processor 102 to send output to the output devices 110. It is noted that the input driver 112 and the output driver 114 are optional components, and that the device 100 will operate in the same manner if the input driver 112 and the output driver 114 are not present.

The external memory 116 may be similar to the memory 104, and may reside in the form of off-chip memory. Additionally, the external memory may be memory resident in a server where the memory controller 115 communicates over a network interface to access the external memory 116. For example, the external memory may be a dynamic random access memory (DRAM) that is external to the SOC 101. In addition, the external memory 116 may be external to the system 100.

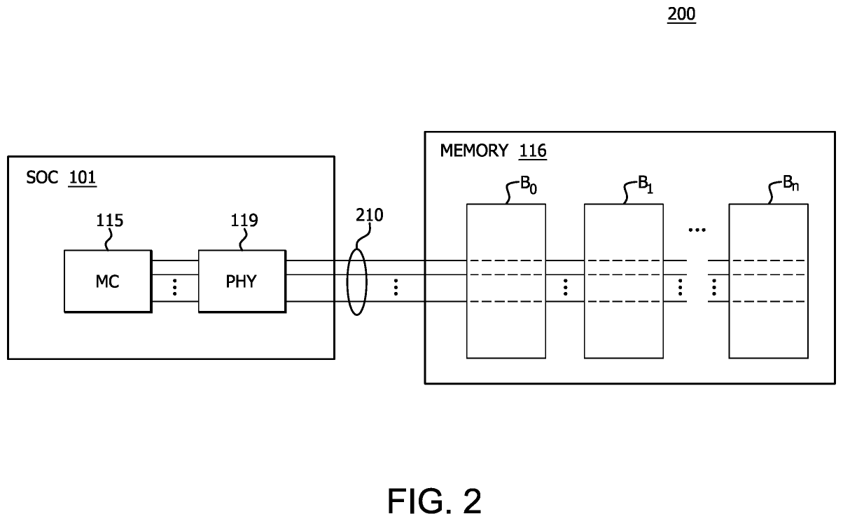

FIG. 2 is a block diagram of a portion of the example system 100 of FIG. 1. In particular, FIG. 2 shows the memory controller 115 (designated, for example, as MC and a physical layer circuitry (PHY) 119 as part of the SOC 101. The PHY 119 is in communication with memory banks of external memory 116 (designated B₀, B₁, . . . , Bₙ). The MC 115 controls data flows to the PHY 119, which then effects reads and writes to the memory banks of the memory 104 over bus wires 210.

Each of the bus wires 210 communicates from the PHY 119 to the memory banks B of the external memory 116 to allow data to be written to the memory banks B when a command to write data is received by the PHY 119. In addition, each of the bus wires 210 allows data to be transmitted back from the memory banks B to the PHY when a command to read data is received by the PHY 119.

Although the memory controller 115 is shown as communicating with the external memory 116 (DRAM), it should be noted that the memory controller may also be communicating in the context of the description below with memory 104 or any other memory utilized by the system 100.

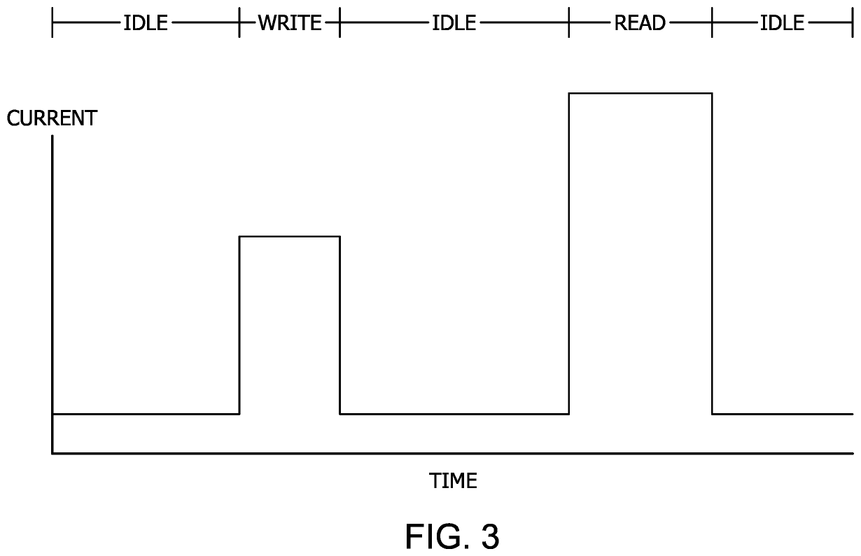

As shown in FIG. 2, when an operation is requested of the PHY 119 from the memory controller 115 to perform an operation on data in the memory 116, for example, a signal is sent by the memory controller 115 to the PHY 119 to perform the operation. For example, when a read or write operation is passed to the PHY 119 from the MC 115, the PHY 119 transmits and receives from the memory 104 over the bus wires 210. These operations utilize power when transitioning from an idle state to a read or write state, as described below in FIG. 3.

More specifically, referring back to FIGS. 1 and 2 together, when a command is effected by the memory controller 115 to perform a read or write operation, the memory controller 115 passes the command to the PHY 119 for actual transmission or reception of the data. Each of the bus wires 210 is connected to the memory banks B and the PHY 119 allows the data to be transmitted to one or more of the memory banks B depending on the need of the read or write operation.

As discussed previously, each bus wire 210 transmits/carries information independently to one another. Accordingly, each bus wire 210 incurs a power increase when that bus wire 210 is utilized to transmit data.

For example, when a first bus wire of the bus wires 210 is energized to transmit data from the PHY 119 to the memory banks B in the external memory 116, a power increase occurs to power the transmission. As additional bus wires 210 are energized, additional power increases are incurred to power the additional bus wires.

Depending on the number of writes or reads that occur, the PHY 119 incurs different power requirements. That is, as additional simultaneous reads or writes occur, the power is increased in order to power the PHY 119 to transmit over the bus wires 210, or to power the bus wires 210 to receive data from the DRAM.

FIG. 3 is an example timing diagram depicting a read and write operation to a memory area of the example system 100 of FIG. 1, for example, in the PHY 119. As shown in FIG. 3, the x axis depicts the passage of time and the y axis depicts power (current).

As can be seen in FIG. 3, during an idle period, the power utilization in the PHY 119 is at a low level. In this state, the power requirements at the PHY 119 are low as the circuitry in the PHY 119 does not need to be energized in order to write or read data.

When a write operation or a read operation is effected, the power level increases to a higher level. As shown in FIG. 3, a write operation utilizes less power than a read operation, but this is shown as an example only. For example, when the memory controller 115 sends a command to the PHY 119 to perform a write, the power requirements at the PHY 119 increase.

This increase described above allows the PHY 119 circuits to power up in order to transmit the data to the DRAM banks B. In addition, when the memory controller 115 sends a command to the PHY 119 to perform a read operation, the power in the PHY is increased in order to allow the PHY 119 circuitry directed toward receiving data from the DRAM banks B to be energized.

Additionally, the bus wires 210 are energized in either a read or write operation in order transmit the data along the wires. More power is incurred as additional wires of the bus wires 210 are utilized to transmit or receive data.

During the idle periods shown in FIG. 3, current requirements (and therefore power requirements) are low as circuitry is not energized in order to allow the PHY 119 to transmit or receive data. Again, during a write operation, the current increases to a higher level to accommodate the circuitry requirements in the PHY 119 to effect the write. As also shown in FIG. 3, during a read operation, the current is increased at an even higher level than for the read in the PHY 119.

For example, when the write is to occur, the circuitry in the PHY 119 to transmit data over the wires 210 is energized by increasing the current. When the read operation is to occur, the current is increased in the PHY 119 circuitry to energize the circuitry to receive the data from the DRAM banks B over the wires 210.

As can be seen in FIG. 3, the current increases proceeding from the idle state to either the read operation state or the write operation state increase the current draw from the power supply significantly. Also, when the power requirements are removed after each the write operation and the read operation are completed, the power drop in current decreases significantly back down to the idle level.

These large increases and decreases may cause the power supply to be unable to properly provide power for all of the increases, particularly when many simultaneous reads or writes on the bus wires 210 are needed. That is, each read and write on each of the bus wires 210 requires its own increase in power from the idle state to the read or write state.

Although each of the DRAM banks B may only see some transactions (e.g., read or writes), the PHY 119 is utilized for all of the transactions and therefore is required to increase or decrease circuit power requirements for all transactions. Accordingly, by smoothing the current requirements for each of the reads and writes on all the DRAM banks that are scheduled, the increase, or jump, in current from the idle states to the level of power required to perform read or write operations can aid in avoiding large drains on the power supply.

That is, by incrementally increasing the current level in the PHY 119 from the idle power level to the read level or the write level power requirement prior to the read or write operation, the strain on the power supply is reduced. Further, by lowering the current level in the PHY 119 from either the read or write power levels back down to the idle state power levels, the power strain on the power supply is further managed.

In order to manage the power increases and decreases before and after a read and write operation, a simulated write (phantom write) may be performed. The simulated write simulates a write operation to increase the power from the idle state at a level above the idle state. However, the simulated write may not increase the current level in the PHY 119 to complete level utilized for either a read or write operation.

Referring back to FIG. 2, the memory controller 115 sends a simulated write (phantom write) to the PHY 119, which will be described in more detail below. However, briefly again, the simulated write is an operation that causes the PHY 119 to increase power partially, without enabling the output of the PHY 119 to transmit to the memory banks (e.g., in memory 104).

Additionally, as described in more detail below, the simulated write may increase the power level current to a level that is above the idle state power level, but not at the full current level that is utilized to perform an actual read or write operation. This may be performed by a technique of subchannel throttling, where the actual increase is throttled incrementally during either the increase in the current level to raise it to the read or write power level, or the decrease in the current level from the read or write operation to bring it back down to the idle current level.

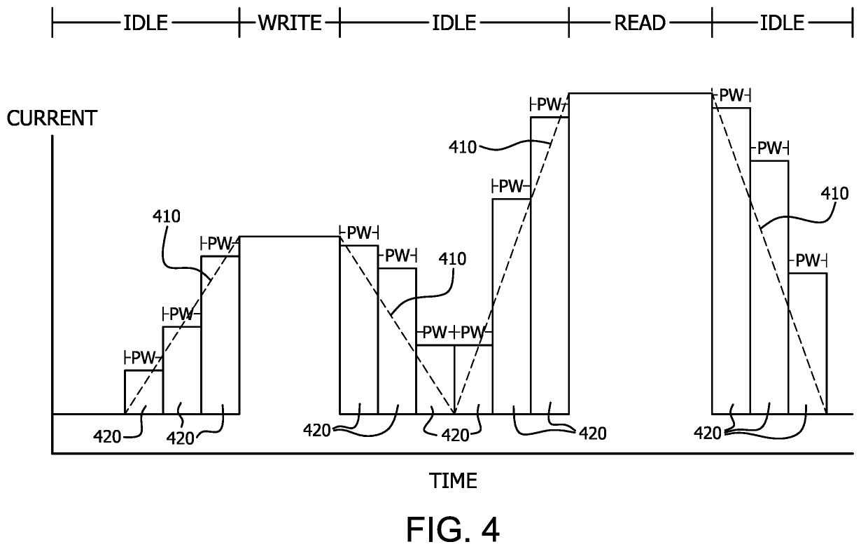

FIG. 4 is an example timing diagram depicting a read and write operation to a memory area including a series of simulated writes. FIG. 4 depicts a similar diagram to the timing diagram in FIG. 3. However, the timing diagram in FIG. 4 shows the effects of sending simulated write operations to the PHY 119.

For example, as shown in FIG. 4, a smoothed series of dashed lines 410 depict an intended triangle to raise the power level incrementally by sending simulated writes (PWs) 420.

Although a more detailed description of the method for performing a simulated write is described below, briefly, this is effected by detecting where a write or read is about to occur and scheduling a series of simulated writes (420) to raise the power level incrementally prior to the read or write event.

These simulated writes are scheduled internally by the memory controller 115 so as to not interfere with, and cause latencies with the actual read and write transactions. As can be seen in FIG. 4, each simulated write 420 causes a power increase by drawing current from the power supply that increases the power level from the idle state power level to a level higher than the idle state power level.

However, as can also be seen in FIG. 4, each simulated write 420 increases by an additional step from the idle power state level to the read or write state power level. This incremental stepping up of the power level with each simulated write 420 smooths the current draw from the power supply and effectively replicates the triangle 410, causing a smoother increase in power from the idle state power level to the read or write power level.

This incremental increase in power level may be accomplished by sending data of a predefined value from the memory controller without enabling the output of the transmitter of the PHY 119 (described below). That is, a first number of bytes may be used/transferred from the memory controller 115 to the PHY 119 in order to effect the first simulated write 420. A second larger amount of bytes may be utilized to increase the power more in the second simulated write 420, and so on, in order to raise the current level to the current level of the actual read or write operation.

Once the event is complete, a series of simulated writes is then scheduled to transition the power level back down to idle. That is, a simulated write 420 is introduced at a byte level that is lower than the actual read or write operation once the read or write event is complete. Each subsequent simulated write 420 is then introduced at a byte level lower than the previous simulated write 410 until the current level is transitioned back down to the idle power level.

Accordingly, the power level increases in a fairly smooth increase along the slope 410 as each simulated write 420 is incrementally increased in byte size to draw more power, and then decreases along a declining slope 410 after the read or write event has occurred by each simulated write 420 being incrementally decreased in byte size. The smoothing of the power curve ramping up to each read or write operation and transitioning back down to the idle power state at the end of each read or write event eases the strain on the power supply system.

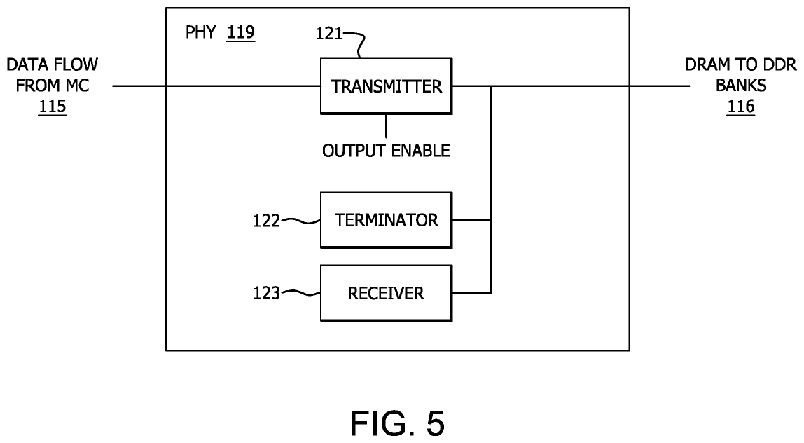

To further describe the operation of the simulated write, FIG. 5 is an example block diagram of a PHY layer 119 during a simulated write operation. The PHY 119 includes a transmitter 121, which includes an output enable input that turns the transmitter 121 on or off. In addition, the PHY 119 includes a termination circuit 122 and a receiver 123.

The transmitter 121, termination circuit 122 and the receiver 123 are in communication with the DRAM memory 116 (e.g., DDR banks) to transmit information during a write operation and to receive information during a read operation. The communication may occur over the bus wires 210 depicted in FIG. 2. The PHY 119 receives data flows from the memory controller 115 which include read operations, write operations and simulated write operations which do not toggle the output enable.

As described above, during an actual read or write operation, the output enable of the PHY 119 is enabled (e.g., set to 1) to enable the PHY 119 to transmit and receive data from the DRAM banks. During a simulated write, although data is transferred between the memory controller 115 and the PHY 119, causing some power increase in the PHY 119, the output enable is not enabled (e.g., set or remains at 0). Accordingly, the transmit and receive circuitry is not energized and active for an actual read and write operation.

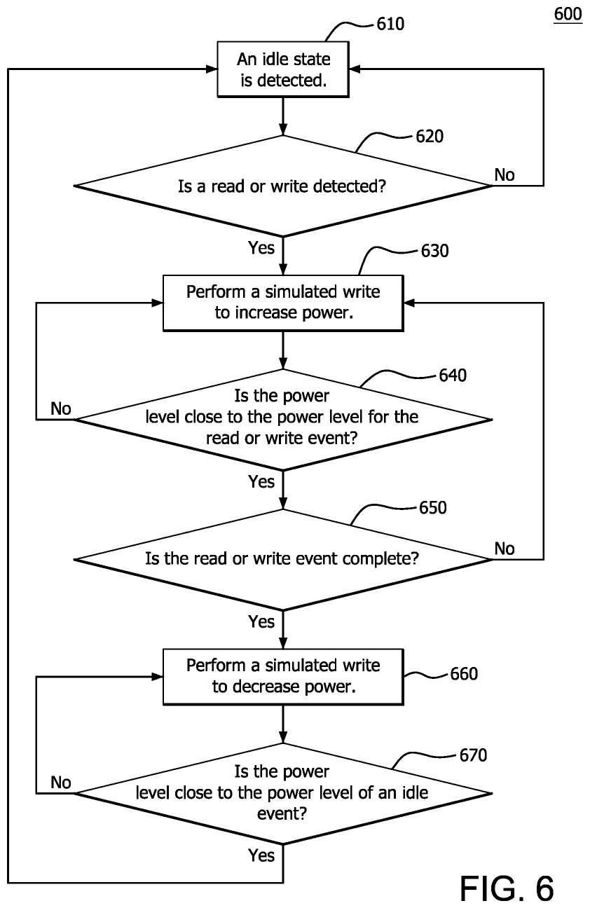

FIG. 6 is a flow diagram of an example method 600 of performing a simulated write operation in accordance with an embodiment.

In step 610, and idle state is detected or determined (e.g., by the memory controller 115). In order to properly schedule simulated writes from the idle state, the memory controller 115 then detects whether a read or write is to occur (step 620).

If a read or write is to occur (step 620), then a simulated write is performed to increase power prior to the read or write event (step 630). The simulated write instructs the PHY 119 to increase power from the idle power state to a higher power level state. However, the simulated write does not enable the output enable bit of the transmitter 121 of the PHY 119. For example, the simulated write in step 630 does not toggle the output enable bit from 0 to 1 and does not change the state of the internal interface between the PHY 119 and the DRAM.

If the power level of the PHY 119 is not close to the level needed for the read or write operation (step 640), then the memory controller 115 performs another simulated write operation (step 630). In the subsequent simulated write operation, the power level is increased higher than the power level of the first simulated write operation.

In this manner, an incremental increase in power along a smooth increased slope is effectively created, such as the slope 410 shown in FIG. 4. That is, each subsequent simulated write in step 630 has its power increased similar to the example simulated writes 420 shown in FIG. 4 prior to a read or write operation

That is, each subsequent simulated write 420 causes an increase in power level higher than the previous simulated write 420. This allows the power to be ramped up in steps toward the power level needed to perform an actual read or write operation.

If the power level is close to the power level needed for the read or write operation in step 640, and the read or write event is completed (step 650), then the memory controller 115 performs simulated write operations 660 to decrease the power level back down to the idle power level until the power level is close to the idle power level (step 670).

That is, each subsequent simulated write in 660 is less in power than the previous simulated write operation similar to the example simulated writes 420 shown in FIG. 4 after a read or write operation.

As mentioned previously, simulated write operations may be varied in power via the memory controller instructing the PHY to modulate the number of data pins to perform the simulated write. For example, utilizing individual byte enables, a granularity of 8 data pins may be effected for performing simulated writes. That is, each step up or down may be an increase or decrease of 8 data pins in the subsequent simulated write.

It should also be noted that criteria may be utilized to schedule simulated writes. For example, simulated writes may be scheduled in between load stepping and load release (idle-read) steps. The memory controller may be aware when the current is going from active to idle so it can schedule the simulate writes according within active states (read vs. write). The memory controller may also schedule for a simulated write a predefined period between a read or write operation.

Because of the DDR protocol, a gap is required between read and write operation. Accordingly, the memory controller may schedule gaps between read and write operations where the simulated writes may be performed. Since simulated writes are internal to the memory controller and PHY, no communication of the simulated write is communicated to the DRAM. Accordingly, simulated writes may be scheduled even in cases that are otherwise disallowed by the DDR protocol.

Additionally, the simulated write operations may be varied in power via the memory controller instructing the PHY to modulate the number of data pins to perform the simulated write. This may be implemented, for example, with individual byte enables, enabling a granularity of 8 data pins.

The methods provided can be implemented in a general-purpose computer, a processor, or a processor core. Suitable processors include, by way of example, a general purpose processor, a purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine. Such processors can be manufactured by configuring a manufacturing process using the results of processed hardware description language (HDL) instructions and other intermediary data including netlists (such instructions capable of being stored on a computer readable media). The results of such processing can be maskworks that are then used in a semiconductor manufacturing process to manufacture a processor which implements features of the disclosure. Further, although the methods and apparatus described above are described in the context of controlling and configuring memory physical links, the methods and apparatus may be utilized in any interconnect protocol where link width is negotiated.

The methods or flow charts provided herein can be implemented in a computer program, software, or firmware incorporated in a non-transitory computer-readable storage medium for execution by a general purpose computer or a processor. Examples of non-transitory computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). For example, the methods described above may be implemented in the processor 102 or on any other processor in the computer system 100. Additionally, the methods described above may be performed in a controller, processor or circuitry within any component (e.g., a component of the SOC 101).

What is claimed is:

1. A method for performing a simulated write in a computer system, comprising:
sending a simulated write operation to a physical layer circuitry (PHY) to increase circuit power without enabling the output of the PHY until a memory operation begins; and
responsive to the memory operation being complete, sending a simulated write operation to the PHY to decrease circuit power.

2. The method of claim 1 wherein the simulated write instructs the PHY to increase circuit power to a level above an idle state that is below a power level state of the memory operation.

3. The method of claim 2 wherein a first simulated write increases the circuit power of the PHY a first power level above the idle state.

4. The method of claim 3 wherein a second simulated write increases the circuit power of the PHY a second power level above the first power level.

5. The method of claim 4, further comprising performing the first simulated write before the second simulated write.

6. The method of claim 5 wherein the first simulated write and the second simulated write are performed before a memory operation.

7. The method of claim 4, further comprising performing the first simulated write after the second simulated write.

8. The method of claim 7 wherein the first simulated write and the second simulated write are performed at the completion of a memory operation.

9. The method of claim 4 wherein the first simulated write includes a first number of data bytes and the second simulated write includes a second number of data bytes that is more than the first number of data bytes.

10. The method of claim 1, further comprising scheduling the simulated write based upon a criteria.

11. The method of claim 10 wherein the criteria includes one or more of the following: in between a load step and load release of a memory operation, a scheduled time between a read operation and a write operation, or a predefined period between a read operation or a write operation.

12. A computer system for performing a simulated write, comprising:
a physical layer circuitry (PHY); and
a memory controller operatively coupled with and in communication with the PHY, the memory controller configured to:
responsive to a scheduled memory operation send a simulated write operation to the PHY to increase circuit power without enabling the output of the PHY until the memory operation begins; and
responsive to the memory operation being complete, send a simulated write operation to the PHY to decrease circuit power.

13. The computer system of claim 12 wherein the simulated write instructs the PHY to increase circuit power to a level above an idle state that is below a power level state of the memory operation.

14. The computer system of claim 13 wherein a first simulated write increases the circuit power of the PHY a first power level above the idle state.

15. The computer system of claim 14 wherein a second simulated write increases the circuit power of the PHY a second power level above the first power level.

16. The computer system of claim 15, further comprising the memory controller sending the first simulated write before the second simulated write.

17. The computer system of claim 16 wherein the first simulated write and the second simulated write are sent before a memory operation.

18. The computer system of claim 15, further comprising the memory controller sending the first simulated write after the second simulated write.

19. The computer system of claim 18 wherein the first simulated write and the second simulated write are sent at the completion of a memory operation.

20. A memory controller operatively coupled with and in communication with a physical layer circuitry (PHY), the memory controller comprising:
a processor, the processor configured to:
responsive to a scheduled memory operation, send a simulated write operation to the PHY to increase circuit power without enabling the output of the PHY until the memory operation begins; and
responsive to the memory operation being complete, send a simulated write operation to the PHY to decrease circuit power.
